(19) United States
(12) Patent Application Publication
(10) Pub. No.: US 2026/0206172 A1
(43) Pub. Date: Jul. 16, 2026

(54) BUS BAR MODULE FOR A SERVER RACK

(71) Applicant: Dell Products L.P., Round Rock, TX (US)

(72) Inventors: Eduardo Escamilla, Round Rock, TX (US); Edward Gabriel Bernard Crofts, Newton, MA (US); Andrew E. Barada, Newton, MA (US); Walter R. Carver, Round Rock, TX (US); Jason Charles Pritchard, Hopkinton, MA (US)

(21) Appl. No.: 19/024,728

(22) Filed: Jan. 16, 2025

(51) Int. Cl. H05K 7/14

(52) U.S. Cl. CPC H05K 7/1492

(57) ABSTRACT

Server rack, including a first rack unit; a server positioned within the first rack unit, the server including a first bus bar clip; a second rack unit adjacent to the first rack unit; a power shelf positioned within the second rack unit at a first end of the rack unit, the power shelf including a second bus bar clip; a fixed shelf positioned within the second rack unit at a second end of the rack unit opposite to the first end, the fixed shelf including a coupling system; a bus bar module including a coupling component, wherein when the bus bar module is coupled to the coupling system of the fixed shelf, the coupling component of the bus bar module contacts the first bus bar clip of the server and the second bus bar clip of the power shelf to place the power shelf in power communication with the server.

### BACKGROUND

### Field of the Disclosure

The disclosure relates generally to a bus bar module for a server rack.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Server racks are designed to securely hold and organize multiple servers, networking equipment, and other hardware components in a data center. They provide efficient use of space, allowing for easy access and maintenance of the equipment. Additionally, server racks often include features like cable management systems and cooling solutions to ensure optimal performance and reliability.

### SUMMARY

Innovative aspects of the subject matter described in this specification may be embodied in a server rack, including a first rack unit; a server positioned within the first rack unit, the server including a first bus bar clip; a second rack unit adjacent to the first rack unit; a power shelf positioned within the second rack unit at a first end of the rack unit, the power shelf including a second bus bar clip; a fixed shelf positioned within the second rack unit at a second end of the rack unit opposite to the first end, the fixed shelf including a coupling system; and a bus bar module including a coupling component, wherein when the bus bar module is coupled to the coupling system of the fixed shelf, the coupling component of the bus bar module contacts the first bus bar clip of the server and the second bus bar clip of the power shelf to place the power shelf in power communication with the server.

Other embodiments of these aspects include corresponding systems and apparatus.

These and other embodiments may each optionally include one or more of the following features. For instance, the bus bar module is configured to route power from the power shelf to the server. The coupling system of the fixed shelf includes a pair of rails, the bus bar module is positioned between the pair of rails. The bus bar module is removably coupled to the coupling system of the fixed shelf. The bus bar module includes an ejector configured for decoupling of the bus bar module from the first bus bar clip of the server and the second bus bar clip of the power shelf. When the bus bar module is coupled to the coupling system of the fixed shelf, the bus bar module is configured to prevent access to an ejector of the server. The bus bar module includes a fastener configured to maintain a positioning of the bus bar module.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates a perspective view of a server rack.

FIG. 3 illustrates a perspective view of the power shelf.

FIG. 4 illustrates a back view of the server and the power shelf.

FIG. 5A illustrates a perspective view of the server and the power shelf before coupling with a bus bar module, the bus bar module in a partially transparent view.

FIG. 5B illustrates a perspective view of the server and the power shelf before coupling with the bus bar module.

FIG. 5C illustrates a side view of the server and the power shelf before coupling with the bus bar module.

FIG. 5D illustrates a side view of the server and the power shelf before coupling with the bus bar module, the bus bar module in a partially transparent view.

FIG. 6A illustrates a perspective view of the server and the power shelf after coupling with the bus bar module.

FIG. 6B illustrates a side view of the server and the power shelf after coupling with the bus bar module.

FIG. 6C illustrates a side view of the server and the power shelf after coupling with the bus bar module, the bus bar module in a partially transparent view.

### DESCRIPTION OF PARTICULAR EMBODIMENT(S)

This disclosure discusses a bus bar module for a server rack. In short, the bus bar module can route power from a power shelf to a server. The bus bar module can connect to a bus bar clip of the power shelf and a bus bar clip of the server to complete the connection. The bus bar module is mounted on a fixed shelf attached to rails of the power shelf.

Specifically, this disclosure discusses a server rack, including: a first rack unit; a server positioned within the first rack unit, the server including a first bus bar clip; a second rack unit adjacent to the first rack unit; a power shelf positioned within the second rack unit at a first end of the rack unit, the power shelf including a second bus bar clip; a fixed shelf positioned within the second rack unit at a second end of the rack unit opposite to the first end, the fixed shelf including a coupling system; a bus bar module including an outer shell and a coupling component positioned within the outer shell, the coupling component including a first connection interface and a second connection interface, wherein when the bus bar module is coupled to the coupling system of the fixed shelf, the first connection interface of the coupling component of the bus bar module contacts the first bus bar clip of the server and the second connection interface of the coupling component of the bus bar module contacts the second bus bar clip of the power shelf to place the power shelf in power communication with the server.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such as wires, optical fibers, microwaves, radio waves, and other electromagnetic and/or optical carriers; and/or any combination of the foregoing.

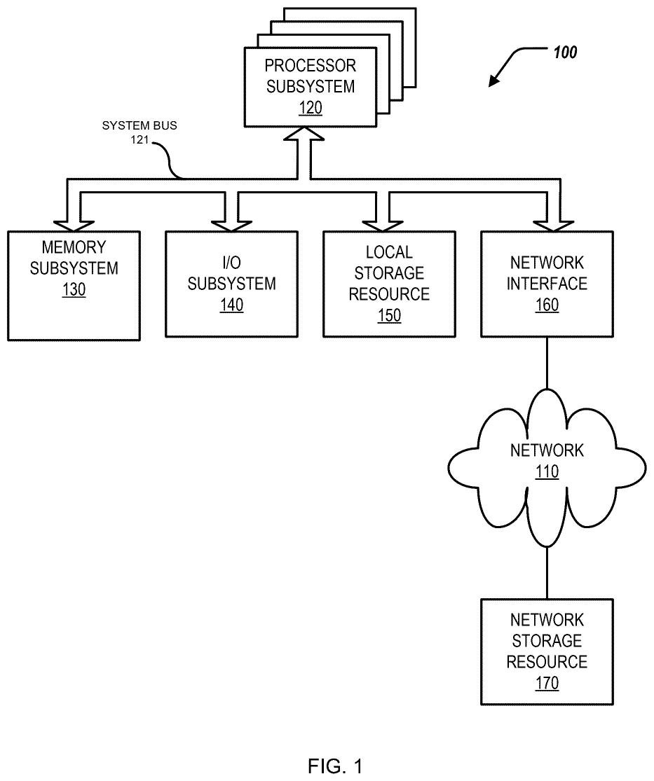

Particular embodiments are best understood by reference to FIGS. 1-6 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include one or more processing resources such as a central processing unit (CPU), microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system 100). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other types of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other types of rotating storage media, flash memory, EEPROM, and/or other types of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g., corporate) network. The network may be implemented as, or may be a part of, a storage area network (SAN), a personal area network (PAN), a local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g., customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet, or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

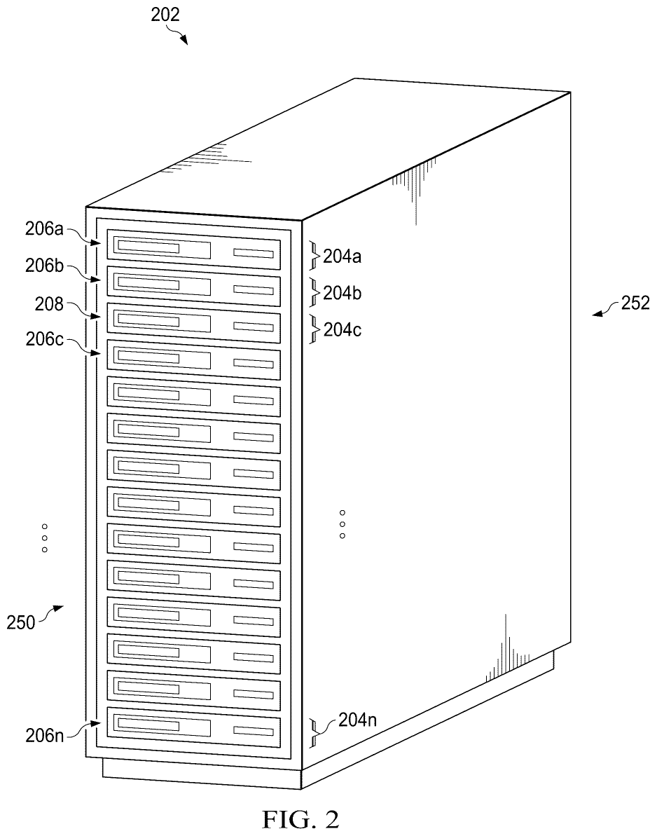

FIG. 2 illustrates a perspective view of the server rack 202. The server rack 202 includes rack units 204a, 204b, 204c . . . , 204n (collectively referred to as rack units 204); however, the server rack 202 can include any number of rack units 204. The server rack 202 can further include servers 206a, 206b, 206c, . . . , 206n (collectively referred to as servers 206); however, the server rack 202 can include any number of servers 206. The servers 206 are positioned at respective rack units 204. In other words, the servers 206 are physically coupled to the respective rack units 204. In other words, the servers 206 are physically coupled to the server rack 202 at respective rack units 204. In other words, the servers 206 are positioned within a respective rack unit 204. For example, a first server 206a is positioned within the rack unit 204a; and a second server 206b is positioned within the rack unit 204b.

The server rack 202 can further include a power shelf 208; however, the server rack 202 can include any number of power shelves 208. The power shelf 208 can be positioned at rack unit 204c. In other words, the power shelf 208 is physically coupled to the rack unit 204c. In other words, the power shelf 208 is positioned at rack unit 204c.

In short, a bus bar module can route power from the power shelf 208 to the server 206. The bus bar module can connect to a bus bar clip of the power shelf 208 and a bus bar clip of the server 206 to complete the connection. The bus bar module is mounted on a fixed shelf attached to rails of the power shelf 208.

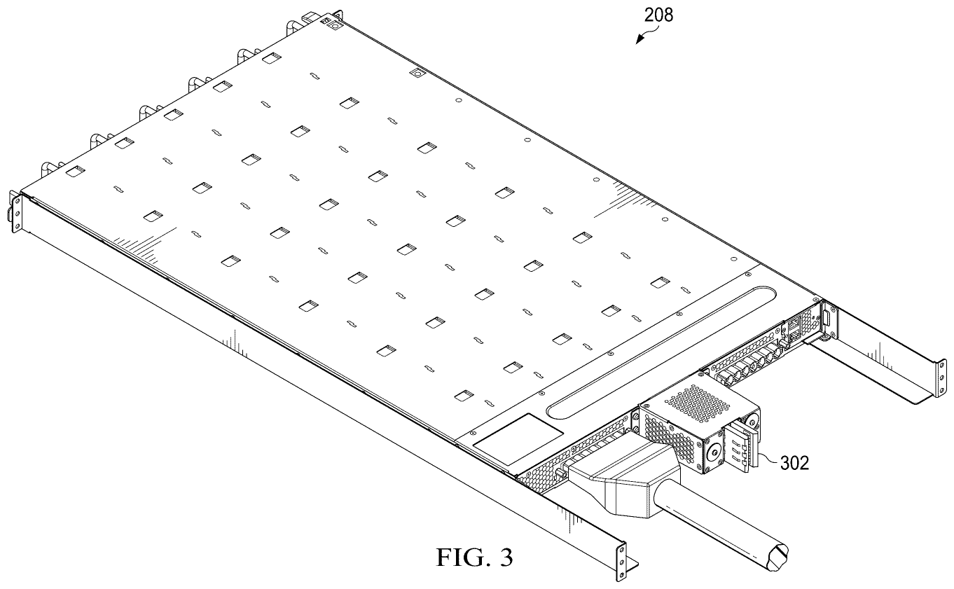

FIG. 3 illustrates a perspective view of the power shelf 208. The power shelf 208 can include a bus bar clip 302.

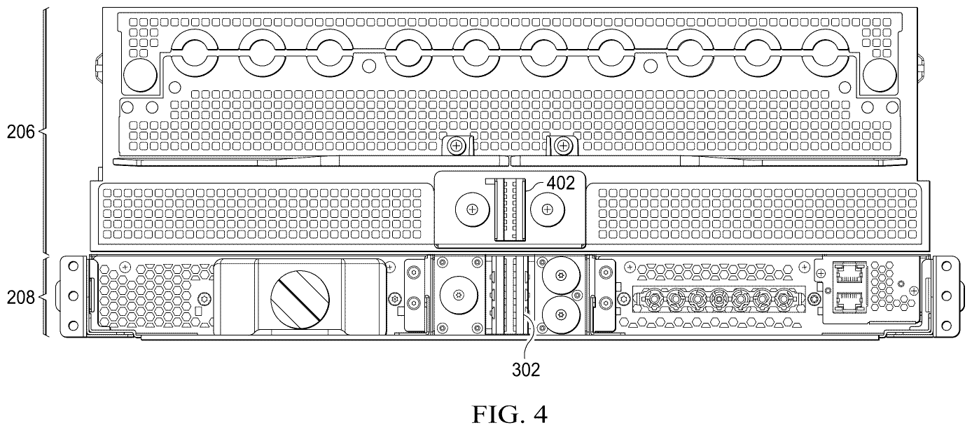

FIG. 4 illustrates a back view of the server 206 and the power shelf 208. The power shelf 208 can include the bus bar clip 302, and the server 206 can include a bus bar clip 402.

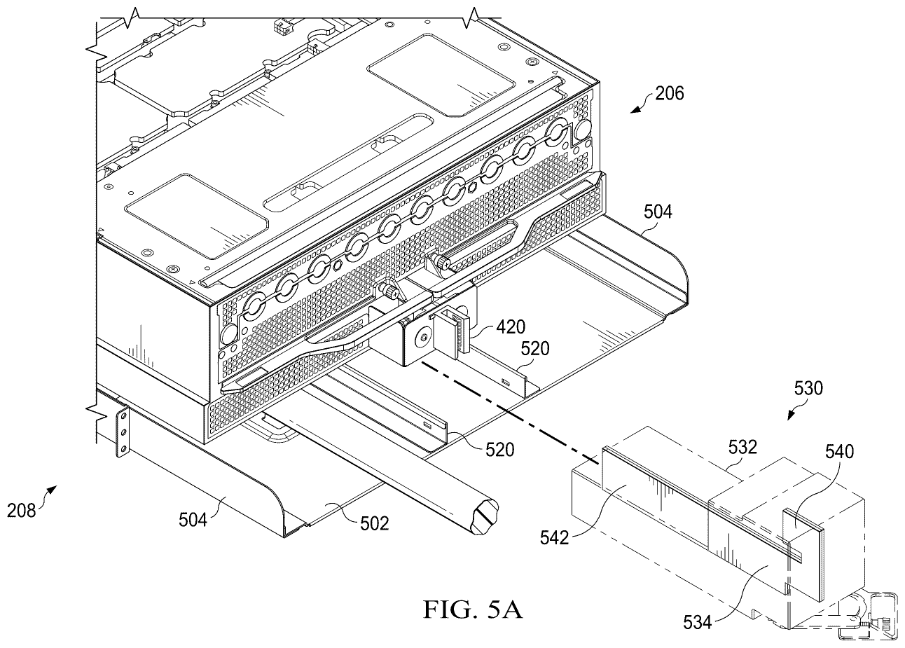

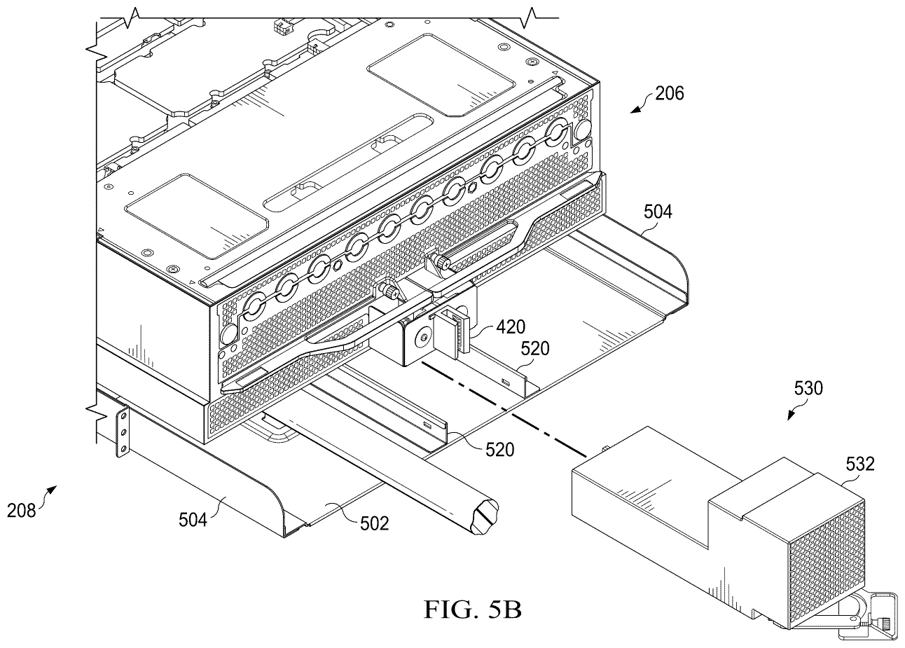

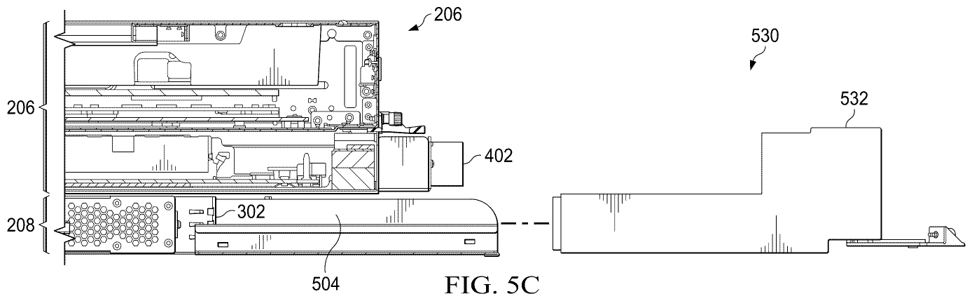

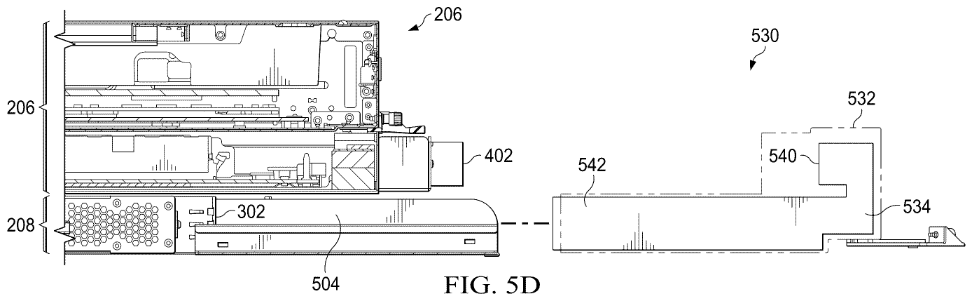

FIG. 5A illustrates a perspective view of the server 206 and the power shelf 208 before coupling with a bus bar module, the bus bar module in a partially transparent view; FIG. 5B illustrates a perspective view of the server 206 and the power shelf 208 before coupling with a bus bar module; FIG. 5C illustrates a side view of the server 206 and the power shelf 208 before coupling with a bus bar module; and FIG. 5D illustrates a side view of the server 206 and the power shelf 208 before coupling with a bus bar module, the bus bar module in a partially transparent view.

Referring to FIGS. 5A-5D, for ease of illustration, the server 206 and the power shelf 208 are shown without the rack units 204. Referring to FIGS. 2-5D, the server 206b can be positioned within the rack unit 204b and the power shelf 208 can be positioned within the rack unit 204c. A fixed shelf 502 can be positioned within the rack unit 204c as well. Specifically, the fixed shelf 502 is attached/coupled to rails 504 of the power shelf 208. The rack unit 204b that the server 206b is coupled to can be adjacent to the rack unit 204c that the power shelf 208 is coupled to. In some examples, the power shelf 208 is positioned at a first end 250 of the rack unit 204; and the fixed shelf 502 is positioned at a second end 252 of the rack unit 204c, with the second end 252 being opposite to the first end 250.

The fixed shelf 502 can include a coupling system, and in particular, a pair of rails 520.

A bus bar module 530 (or bus bar shunt module 530) can be removably coupled to the rails 520. The bus bar module 530 can include an outer shell 532 and a coupling component 534 positioned within the outer shell 532. The coupling component 534 can include a first connection interface 540 and a second connection interface 542. The first connection interface 540 is connected to the second connection interface 542. The coupling component 534 can be formed from any conductive material or combination of conductive materials; for example, the coupling component 534 can be formed from copper.

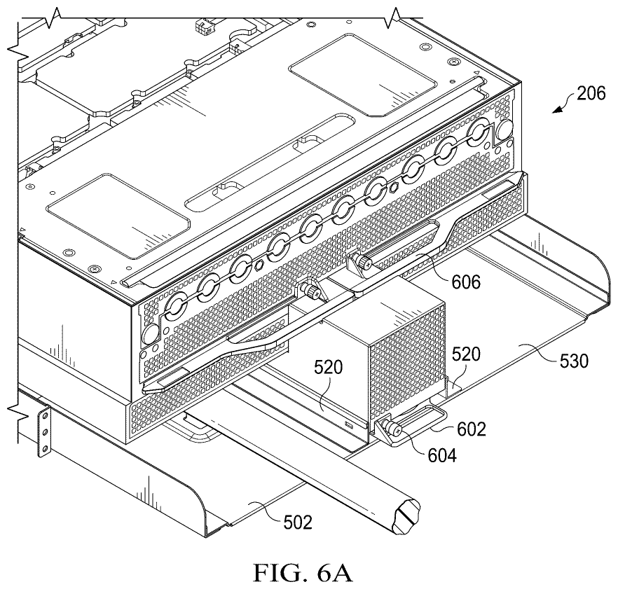

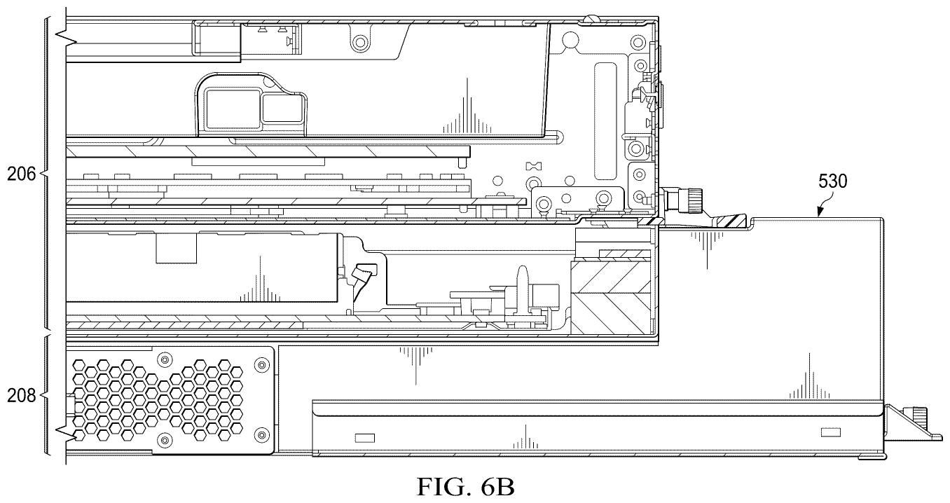

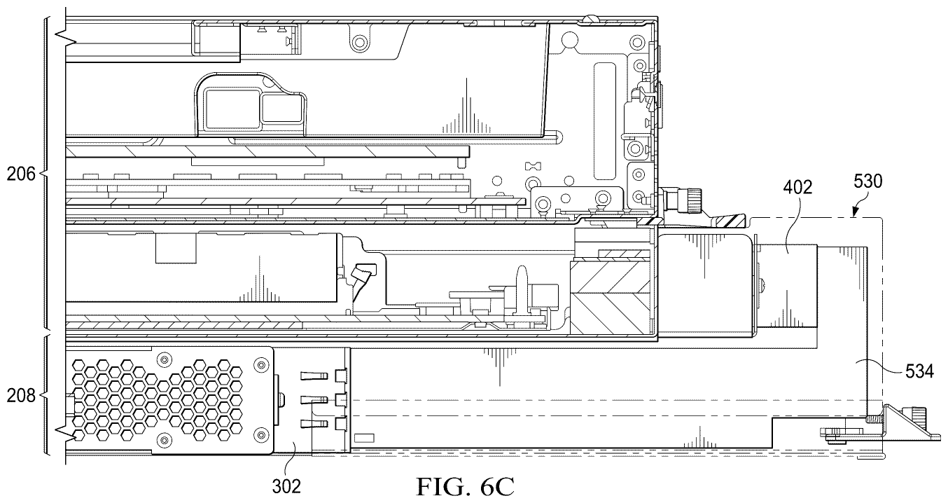

FIG. 6A illustrates a perspective view of the server 206 and the power shelf 208 after coupling with the bus bar module 530; FIG. 6B illustrates a side view of the server 206 and the power shelf 208 after coupling with the bus bar module 530; and FIG. 6C illustrates a side view of the server 206 and the power shelf 208 after coupling with the bus bar module 530, the bus bar module 530 in a partially transparent view.

Referring to FIGS. 2-4 and 6A-6C, the bus bar module 530 can be coupled to the fixed shelf 502, and in particular, positioned between the rails 520 of the fixed shelf 502. To that end, when the bus bar module 530 is coupled to the fixed shelf 502, the first connection interface 540 (shown in FIGS. 5A-5D) of the coupling component 534 contacts the bus bar clip 402 of the server 206. That is, the first connection interface 540 is coupled to the bus bar clip 402. In some examples, the first connection interface 540 is inserted into the bus bar clip 402. Furthermore, when the bus bar module 530 is coupled to the fixed shelf 502, the second connection interface 542 (shown in FIGS. 5A-5D) of the coupling component 534 contacts the bus bar clip 302 of the power shelf 208. That is, the second connection interface 542 is coupled to the bus bar clip 302. In some examples, the second connection interface 542 is inserted into the bus bar clip 302.

When the first connection interface 540 of the coupling component 534 of the bus bar module 530 contacts the bus bar clip 402 of the server 206 and the second connection interface 542 of the coupling component 534 of the bus bar module 530 contacts the bus bar clip 302 of the power shelf 208, the bus bar module 530 places the power shelf 208 in power communication with the server 206. That is, when the bus bar module 530 is coupled to the bus bar clip 402 of the server 206 and coupled to the bus bar clip 302 of the power shelf 208, the bus bar module 530 facilitates placing the power shelf 208 in power communication with the server 206. In other words, the bus bar module 530 is configured to route power from the power shelf 208 to the server 206 (when the bus bar module 530 is coupled to the bus bar clip 402 of the server 206 and coupled to the bus bar clip 302 of the power shelf 208). In other words, power is routed from the power shelf 208 through the bus bar module 530 and to the server 206.

In some examples, the power shelf 208 is coupled to the rack unit 204c first, the bus bar module 530 is coupled to the power shelf 208 next, and then the server 206 is coupled to the rack unit 204b and then coupled to the bus bar module 530. In some examples, the power shelf 208 is coupled to the rack unit 204c and the server 206 is coupled to the rack unit 204b, with the bus bar module 530 then being coupled to the power shelf 208 and the server 206 simultaneously.

Referring to FIG. 6A, the bus bar module 530 includes an ejector 602. The ejector 602 is configured for decoupling the bus bar module 530 from the bus bar clip 402 of the server 206 and the bus bar clip 302 of the power shelf 208. In other words, the ejector 602 facilitates installation and disconnection of the bus bar module 530 from the server 206 and/or the power shelf 208. The bus bar module 530 can further include a fastener 604. For example, the fastener 604 can include a screw-based fastener. The fastener 604 is configured to maintain a positioning of the bus bar module 530. That is, when the bus bar module 530 is coupled to the power shelf 208 and the server 206, the fastener 604 facilitates maintaining the coupling of the bus bar module 530 to the power shelf 208 and the server 206. That is, the fastener 604 prevents uncoupling of the bus bar module 530 from the power shelf 208 and the server 206 (e.g., unintentional uncoupling).

The server 206 can further include an ejector 606. The bus bar module 530, when coupled to the server 206, is configured to prevent access to the ejector 606 of the server 206. That is, the bus bar module 530 prevents the server 206 from being removed from the server rack 202 while the server 206 is powered on by blocking access to the ejector 606.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. A server rack, including:
a first rack unit;
a server positioned within the first rack unit, the server including a first bus bar clip;
a second rack unit adjacent to the first rack unit;
a power shelf positioned within the second rack unit at a first end of the rack unit, the power shelf including a second bus bar clip;
a fixed shelf positioned within the second rack unit at a second end of the rack unit opposite to the first end, the fixed shelf including a coupling system; and
a bus bar module including a coupling component,
wherein when the bus bar module is coupled to the coupling system of the fixed shelf, the coupling component of the bus bar module contacts the first bus bar clip of the server and the second bus bar clip of the power shelf to place the power shelf in power communication with the server.

2. The server rack of claim 1, wherein the bus bar module is configured to route power from the power shelf to the server.

3. The server rack of claim 1,
wherein the coupling system of the fixed shelf includes a pair of rails,
wherein the bus bar module is positioned between the pair of rails.

4. The server rack of claim 1, wherein the bus bar module is removably coupled to the coupling system of the fixed shelf.

5. The server rack of claim 1, wherein the bus bar module includes an ejector configured for decoupling of the bus bar module from the first bus bar clip of the server and the second bus bar clip of the power shelf.

6. The server rack of claim 1, wherein when the bus bar module is coupled to the coupling system of the fixed shelf, the bus bar module is configured to prevent access to an ejector of the server.

7. The server rack of claim 1, wherein the bus bar module includes a fastener configured to maintain a positioning of the bus bar module.

8. A bus bar module for a server rack, including:
an outer shell; and
a coupling component positioned within the outer shell, the coupling component including a first connection interface and a second connection interface,
wherein when the bus bar module is coupled to a fixed shelf positioned within a second rack unit of a server rack, the first connection interface of the coupling component contacts a first bus bar clip of a server positioned within a first rack unit of the server rack and the second connection interface of the coupling component contacts a second bus bar clip of a power shelf positioned within the second rack unit of the server rack to place the power shelf in power communication with the server.

9. The bus bar module of claim 8, wherein the bus bar module is configured to route power from the power shelf to the server.

10. The bus bar module of claim 8, wherein the bus bar module is positioned between a pair of rails of the fixed shelf.

11. The bus bar module of claim 10, wherein the bus bar module is removably coupled to the pair of rails of the fixed shelf.

12. The bus bar module of claim 8, further including an ejector configured for decoupling of the bus bar module from the first bus bar clip of the server and the second bus bar clip of the power shelf.

13. The bus bar module of claim 10, wherein when the bus bar module is coupled to the pair of rails of the fixed shelf, the bus bar module is configured to prevent access to an ejector of the server.

14. The bus bar module of claim 8, further including a fastener configured to maintain a positioning of the bus bar module.

15. A server rack, including:
a first rack unit;
a server positioned within the first rack unit, the server including a first bus bar clip;
a second rack unit adjacent to the first rack unit;
a power shelf positioned within the second rack unit at a first end of the rack unit, the power shelf including a second bus bar clip;
a fixed shelf positioned within the second rack unit at a second end of the rack unit opposite to the first end, the fixed shelf including a coupling system; and
a bus bar module including an outer shell and a coupling component positioned within the outer shell, the coupling component including a first connection interface and a second connection interface,
wherein when the bus bar module is coupled to the coupling system of the fixed shelf, the first connection interface of the coupling component of the bus bar module contacts the first bus bar clip of the server and the second connection interface of the coupling component of the bus bar module contacts the second bus bar clip of the power shelf to place the power shelf in power communication with the server.

16. The server rack of claim 15, wherein the first connection interface and the second connection interface are connected to each other.

17. The server rack of claim 15, wherein the bus bar module is configured to route power from the power shelf to the server.

18. The server rack of claim 15,
wherein the coupling system of the fixed shelf includes a pair of rails,
wherein the bus bar module is positioned between the pair of rails.

19. The server rack of claim 15, wherein the bus bar module is removably coupled to the coupling system of the fixed shelf.

20. The server rack of claim 15, wherein the bus bar module includes an ejector configured for decoupling of the bus bar module from the first bus bar clip of the server and the second bus bar clip of the power shelf.
